(19) United States
(12) Patent Application Publication
(10) Pub. No.: US 2026/0164544 A1
(43) Pub. Date: Jun. 11, 2026

(54) WIRING CIRCUIT BOARD

(71) Applicant: NITTO DENKO CORPORATION, Osaka (JP)

(72) Inventors: Syota ISHIKAWA, Osaka (JP); Takashi YAMAMOTO, Osaka (JP); Ikuya HASHIMOTO, Osaka (JP); Ryosuke SASAOKA, Osaka (JP)

(73) Assignee: NITTO DENKO CORPORATION, Osaka (JP)

(21) Appl. No.: 19/400,934

(22) Filed: Nov. 25, 2025

(30) Foreign Application Priority Data
Dec. 6, 2024 (JP) 2024-213174

(51) Int. Cl. H05K 1/02

(52) U.S. Cl. CPC H05K 1/0296

(57) ABSTRACT

A wiring circuit board includes a metal support layer, a conductor layer, an insulating layer, and a circuit pattern in order toward one side in a thickness direction, and the circuit pattern includes a first circuit pattern having a wire and a second circuit pattern electrically connected to the conductor layer and independent from the first circuit pattern. Furthermore, the wiring circuit board includes a wiring portion in which the wire is disposed. In the wiring portion, a width-direction length of the conductor layer in a width direction perpendicular to the thickness direction and a direction in which the wire extends is larger than a width-direction length of at least a portion of the metal support layer in the thickness direction.

### CROSS-REFERENCE TO RELATED APPLICATION

The present application claims priority from Japanese Patent Application No. 2024-213174 filed on Dec. 6, 2024, the content of which is hereby incorporated by reference into this application.

### TECHNICAL FIELD

The present invention relates to a wiring circuit board.

### BACKGROUND ART

Conventionally, there has been known a wiring circuit board including a metal support layer, an insulating layer, and a wire in order toward one side in the thickness direction (for example, see Patent Document 1 below).

### CITATION LIST

### Patent Document

Patent Document 1: Japanese Unexamined Patent Publication No. 2022-147128

### SUMMARY OF THE INVENTION

### Problem To Be Solved By The Invention

Meanwhile, wiring circuit boards are required to further reduce the electrical resistance.

The present invention provides a wiring circuit board capable of reducing the electrical resistance.

### Means For Solving The Problem

The present invention [1] includes a wiring circuit board comprising: a metal support layer, a conductor layer, an insulating layer, and a circuit pattern in order toward one side in a thickness direction, wherein the circuit pattern includes a first circuit pattern having a wire, and a second circuit pattern electrically connected to the conductor layer and independent from the first circuit pattern, wherein the wiring circuit board includes a wiring portion in which the wire is disposed, and wherein in the wiring portion, a width-direction length of the conductor layer in a width direction perpendicular to the thickness direction and a direction in which the wire extends is larger than a width-direction length of at least a portion of the metal support layer in the thickness direction.

The present invention [2] includes the wiring circuit board described in the above-described [1], wherein in the wiring portion, the width-direction length of the conductor layer is larger than a width-direction length of a central portion of the metal support layer in the thickness direction.

The present invention [3] includes the wiring circuit board described in the above-described [1] or [2], wherein in the wiring portion, a width-direction length of one end portion of the metal support layer in the thickness direction and a width-direction length of an other end portion of the metal support layer in the thickness direction are each larger than a width-direction length of a central portion of the metal support layer in the thickness direction.

The present invention [4] includes the wiring circuit board described in the above-described [1] or [2], wherein the metal support layer of the wiring portion has an approximately tapered shape in a cross-sectional view, the approximately tapered shape extending in the width direction toward the one side in the thickness direction from the other side.

The present invention [5] includes the wiring circuit board described in any one of the above-described [1] to [4], wherein the insulating layer includes a through hole, and wherein the second circuit pattern is electrically connected to the conductor layer through the through hole.

The present invention [6] includes the wiring circuit board described in the above-described [5], wherein the first circuit pattern includes a first terminal connected to the wire, wherein the second circuit pattern includes a second terminal, wherein the wiring circuit board further includes a terminal disposition portion in which the first terminal and the second terminal are disposed, and wherein in the terminal disposition portion, the insulating layer includes the through hole, and the second terminal is disposed in the through hole.

The present invention [7] includes the wiring circuit board described in any one of the above-described [1] to [6], wherein in the wiring portion, a ratio of the width-direction length of the conductor layer with respect to a minimum width-direction length of the metal support layer is 1.2 or more.

The present invention [8] includes the wiring circuit board described in any one of the above-described [1] to [7], wherein in the wiring portion, a ratio of the width-direction length of the conductor layer with respect to a width-direction length of a central portion of the metal support layer in the thickness direction is 1.2 or more.

The present invention [9] includes the wiring circuit board described in any one of the above-described [1] to [8], wherein a ratio of a thickness of the conductor layer with respect to a thickness of the metal support layer is 0.003 or more.

### Effects of the Invention

In the wiring circuit board of the present invention, in the wiring portion, a width-direction length of the conductor layer in a width direction perpendicular to the thickness direction and a direction in which the wire extends is larger than a width-direction length of at least a portion of the metal support layer in the thickness direction. Therefore, it is possible to reduce the electrical resistance.

### BRIEF DESCRIPTION OF THE DRAWINGS

FIG. 1 is a plan view of a wiring circuit board as one embodiment of the present invention.

FIG. 2 is a cross-sectional view of the wiring circuit board shown in FIG. 1, taken along line A-A.

FIG. 3 is a cross-sectional view of the wiring circuit board shown in FIG. 1, taken along line B-B.

FIGS. 4A to 4C are process diagrams for explaining a method of producing the circuit board shown in FIG. 3. FIG. 4A shows a conductor layer forming step, FIG. 4B shows an insulating layer forming step, and FIG. 4C shows a circuit pattern forming step.

FIG. 5A and FIG. 5B are process diagrams for explaining the method of producing the circuit board shown in FIG. 3, following FIGS. 4A to 4C. FIG. 5A shows a cover insulating layer forming step, and FIG. 5B shows an etching step.

FIG. 6 is a cross-sectional view of a first modified example of the wiring circuit board of the present invention.

FIG. 7 is a cross-sectional view of a second modified example of the wiring circuit board of the present invention.

FIG. 8 is a cross-sectional view of a third modified example of the wiring circuit board of the present invention.

FIG. 9 is a cross-sectional view of a fourth modified example of the wiring circuit board of the present invention.

FIG. 10 is a cross-sectional view of a fifth modified example of the wiring circuit board of the present invention.

FIG. 11 is a cross-sectional view of a sixth modified example of the wiring circuit board of the present invention.

### DESCRIPTION OF THE EMBODIMENT

### 1. Wiring Circuit Board

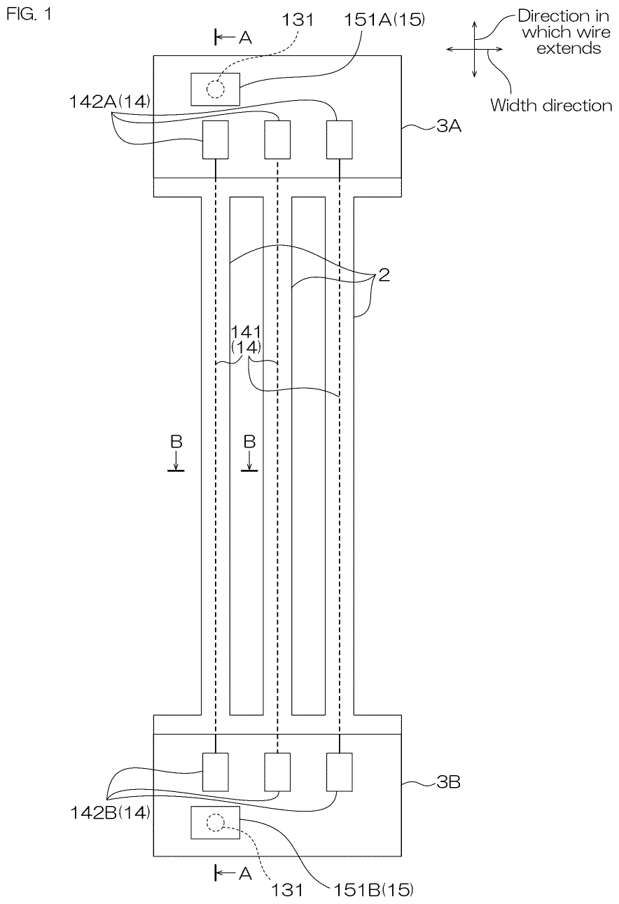

In reference to FIGS. 1 to 3, one embodiment of a wiring circuit board 1 is described.

The wiring circuit board 1 includes a wiring portion 2 in which a wire 141 is disposed. Further, the wiring circuit board 1 preferably further includes a plurality of terminal disposition portions 3 in which a first terminal 142 and a second terminal 151 are disposed. Specifically, as shown in FIG. 1, the wiring circuit board 1 includes a plurality of wiring portions 2 in which the wires 141 are disposed, a terminal disposition portion 3A in which the first terminal 142A and the second terminal 151A are disposed at one side of the wiring portion 2 in a first direction, and a terminal disposition portion 3B in which a first terminal 142B and a second terminal 151B are disposed at the other side of the wiring portion 2 in the first direction.

The first direction is a direction in which the wire 141 described later extends. The first direction (the wire 141 extending direction) is perpendicular to the thickness direction of the wiring circuit board 1. A second direction is a width direction of the wire 141. The second direction (width direction) is perpendicular to both the thickness direction and the first direction.

The wiring circuit board 1 includes a plurality of wiring portions 2. The wiring circuit board 1 shown in FIG. 1 includes three wiring portions 2. In each of the wiring portions 2, a wire 141 of a first circuit pattern 14 described later is disposed. In other words, the wiring portions 2 each include a wire 141 of the first circuit pattern 14 described later. Further, in one wiring portion 2, one wire 141 may be disposed, or a plurality of wires 141 may be disposed.

Each of the plurality of wiring portions 2 is disposed between the terminal disposition portion 3A and the terminal disposition portion 3B in the first direction. In the present embodiment, each of the plurality of wiring portions 2 extends in the first direction. One end portion of each of the plurality of wiring portions 2 in the first direction is continuous with the terminal disposition portion 3A. The other end portion of each of the plurality of wiring portions 2 in the first direction is continuous with the terminal disposition portion 3B. That is, the terminal disposition portion 3B, the wiring portions 2, and the terminal disposition portion 3A are continuous toward one side in the first direction. The shape of each of the plurality of wiring portions 2 in the plan view is not limited, and may be a linear shape, or may be curved.

The plurality of wiring portions 2 are aligned along the second direction (width direction). The plurality of wiring portions 2 are disposed away from each other at intervals in the second direction (width direction).

The wiring portions 2 each have a length in the width direction of, for example, 10 μm to 300 μm, and preferably 50 μm to 250 μm. The width-direction length of each of the wiring portions 2 is a maximum length in the second direction.

In the second direction, an interval between the wiring portions 2 adjacent to each other is, for example, 5 μm to 300 μm, and preferably 10 μm to 250 μm. Regarding the intervals of the wiring portions 2 adjacent to each other, all the intervals of the wiring portions 2 adjacent to each other may be the same, or may be different.

In the second direction, with respect to the width-direction length of each of the wiring portions 2, the ratio (the interval of the wiring portions 2 adjacent to each other/the width-direction length of each of the wiring portions 2) of the interval of the wiring portions 2 adjacent to each other is, for example, 0.5 or more, preferably 1.0 or more, and, for example, 5.0 or less, preferably 4.0 or less.

In the terminal disposition portion 3A, the first terminal 142A of the first circuit pattern 14 and the second terminal 151A of a second circuit pattern 15, which are to be described later, are disposed. In other words, the terminal disposition portion 3A includes the first terminal 142A of the first circuit pattern 14 and the second terminal 151A of the second circuit pattern 15, which are to be described later. In the terminal disposition portion 3B, the first terminal 142B of the first circuit pattern 14 and the second terminal 151B of the second circuit pattern 15, which are to be described later, are disposed. In other words, the terminal disposition portion 3B includes the first terminal 142B of the first circuit pattern 14 and the second terminal 151B of the second circuit pattern 15, which are to be described later.

The terminal disposition portions 3A and 3B are disposed away from each other at an interval in a first direction. Each of the terminal disposition portions 3A and 3B extends in the second direction.

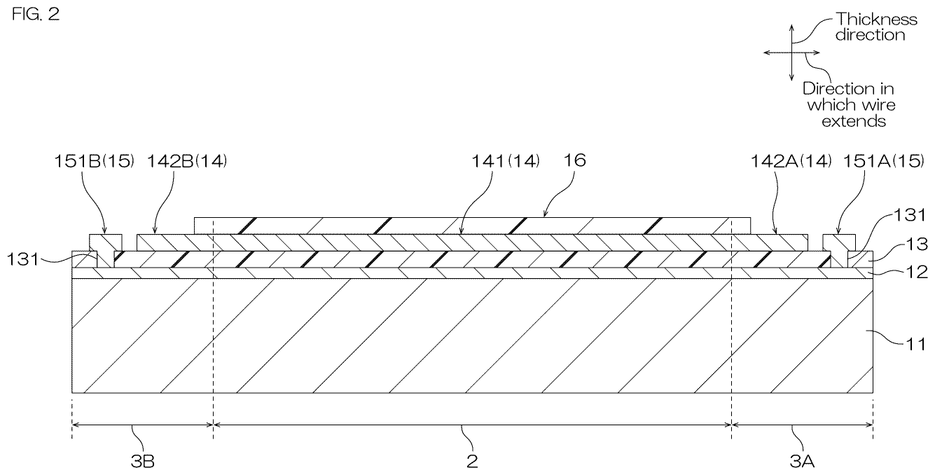

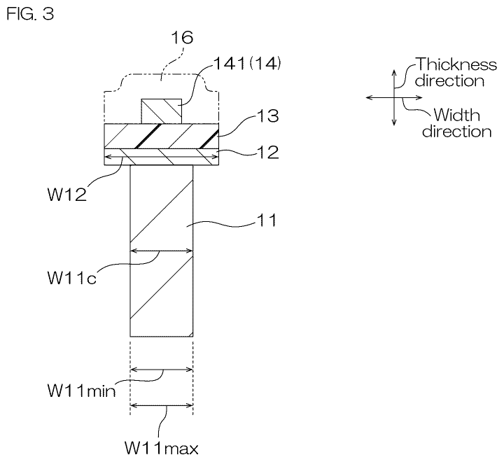

As shown in FIGS. 2 and 3, the wiring circuit board 1 includes a metal support layer 11, a conductor layer 12, an insulating layer 13, and a circuit pattern in order toward one side in the thickness direction.

More specifically, as shown in FIGS. 2 and 3, the wiring portions 2 each include the metal support layer 11, the conductor layer 12 disposed on a one-side surface of the metal support layer 11 in the thickness direction, the insulating layer 13 (base insulating layer) disposed on a one-side surface of the conductor layer 12 in the thickness direction, and the wire 141 of the first circuit pattern 14 disposed on a one-side surface of the insulating layer 13 in the thickness direction. As necessary, the wiring portions 2 each further include a cover insulating layer 16.

Further, as shown in FIG. 2, the terminal disposition portions 3A and 3B includes the metal support layer 11, the conductor layer 12 disposed on the one-side surface of the metal support layer 11 in the thickness direction, the insulating layer 13 disposed on the one-side surface of the conductor layer 12 in the thickness direction and including a through hole 131, the first terminal 142 of the first circuit pattern 14 disposed on the one-side surface of the insulating layer 13 in the thickness direction and connected to the wire 141, and the second terminal 151 of the second circuit pattern 15 disposed in a through hole 131 of the insulating layer 13 and connected to the conductor layer 12.

### (1) Metal Support Layer

The metal support layer 11 is disposed in the wiring portions 2 and the terminal disposition portions 3A and 3B. That is, the wiring portions 2 and the terminal disposition portions 3A and 3B include the metal support layer 11. The metal support layer 11 continues in the wiring portions 2 and the terminal disposition portion 3A and the terminal disposition portion 3B.

The metal support layer 11 is made of metal. Examples of the material of the metal support layer 11 include copper, nickel, cobalt, titanium, iron, and the alloys thereof. Examples of the alloys include a copper alloy and stainless steel. As the material of the metal support layer 11, preferably a copper alloy is used.

The metal support layer 11 has a thickness of, for example, 10 μm to 300 μm, and preferably 50 μm to 250 μm. The thickness of the metal support layer 11 is, for example, 10 μm or more, preferably 50 μm or more, and, for example, 300 μm or less, preferably 250 μm or less.

The metal support layer 11 supports the conductor layer 12, the insulating layer 13, the circuit pattern (the first circuit pattern 14 and the second circuit pattern 15), and the cover insulating layer 16. More specifically, in each of the wiring portions 2, the metal support layer 11 supports the wire 141 of the first circuit pattern 14. In the terminal disposition portion 3A, the metal support layer 11 supports the first terminal 142A of the first circuit pattern 14 and the second terminal 151A of the second circuit pattern 15. In the terminal disposition portion 3B, the metal support layer 11 supports the first terminal 142B of the first circuit pattern 14 and the second terminal 151B of the second circuit pattern 15.

In the wiring portions 2, the metal support layers 11 extend along the wires 141 in the first direction. In the wiring portions 2, the metal support layers 11 are aligned along the second direction. In the wiring portions 2, the metal support layers 11 are disposed away from each other at intervals in the second direction. In each of the wiring portions 2, the shape of the metal support layer 11 viewed from the first direction (in a cross-sectional view) is not particularly limited. In the present embodiment, in each of the wiring portions 2, the shape of the metal support layer 11 in the cross-sectional view is approximately rectangular.

In each of the wiring portions 2, the width-direction length of the metal support layer 11 may be the same, or may be different over the thickness direction. In the present embodiment, in each of the wiring portions 2, the width-direction length of the metal support layer 11 is approximately the same over the thickness direction.

In each of the wiring portions 2, a maximum length W11ₘₐₓ of the metal support layer 11 in the width direction is, for example, 5 μm to 300 μm, preferably 10 μm to 250 μm, more preferably 15 μm to 200 μm. In each of the wiring portions 2, the maximum width-direction length W11ₘₐₓ of the metal support layer 11 is, for example, 5 μm or more, preferably 10 μm or more, more preferably 15 μm or more, and, for example, 300 μm or less, preferably 250 μm or less, more preferably 200 μm or less. In each of the wiring portions 2, the maximum width-direction length W11ₘₐₓ of the metal support layer 11 is the maximum width-direction length of the metal support layer 11 between the one-side surface of the metal support layer 11 in the thickness direction and the other-side surface.

In each of the wiring portions 2, when the maximum width-direction length W11ₘₐₓ of the metal support layer 11 is the above-described lower limit or more, it is possible to support the wire 141. Further, in each of the wiring portions 2, when the maximum width-direction length W11ₘₐₓ of the metal support layer 11 is the above-described upper limit or less, it is possible to miniaturize the wire circuit board 1. In other words, the miniaturization of the wire circuit board 1 is required, and thus in each of the wiring portions 2, the maximum width-direction length W11ₘₐₓ of the metal support layer 11 is preferably the above-described upper limit or less.

In each of the wiring portions 2, a minimum length W11ₘᵢₙ of the metal support layer 11 in the width direction is, for example, 1 μm to 250 μm, preferably 5 μm to 200 μm, more preferably 10 μm to 150 μm. In each of the wiring portions 2, the minimum width-direction length W11ₘᵢₙ of the metal support layer 11 is, for example, 1 μm or more, preferably 5 μm or more, more preferably 10 μm or more, and, for example, 250 μm or less, preferably 200 μm or less, more preferably 150 μm or less. In each of the wiring portions 2, the minimum width-direction length W11ₘᵢₙ of the metal support layer 11 is the minimum width-direction length of the metal support layer 11 between the one-side surface of the metal support layer 11 in the thickness direction and the other-side surface.

In each of the wiring portions 2, when the minimum width-direction length W11ₘᵢₙ of the metal support layer 11 is the above-described lower limit or more, it is possible to support the wire 141. Further, in each of the wiring portions 2, when the minimum width-direction length W11ₘᵢₙ of the metal support layer 11 is the above-described upper limit or less, it is possible to miniaturize the wire circuit board 1.

In each of the wiring portions 2, a central portion of the metal support layer 11 in the thickness direction has a length W11_{c} in the width direction of, for example, 1 μm to 250 μm, preferably 5 μm to 200 μm, more preferably 10 μm to 150 μm. In each of the wiring portions 2, the width-direction length W11_{c} of the central portion of the metal support layer 11 in the thickness direction is, for example, 1 μm or more, preferably 5 μm or more, more preferably 10 μm or more, and, for example, 250 μm or less, preferably 200 μm or less, more preferably 150 μm or less.

In each of the wiring portions 2, when the width-direction length W11_{c} of the central portion of the metal support layer 11 in the thickness direction is the above-described lower limit or more, it is possible to support the wire 141. Further, in each of the wiring portions 2, when the width-direction length W11_{c} of the central portion of the metal support layer 11 in the thickness direction is the above-described upper limit or less, it is possible to miniaturize the wire circuit board 1.

In each of the wiring portions 2, the width-direction length W11_{c} of the central portion of the metal support layer 11 in the thickness direction may be the same as the maximum width-direction length W11ₘₐₓ of the metal support layer 11, or the same as the minimum width-direction length W11ₘᵢₙ of the metal support layer 11. In each of the wiring portions 2, the width-direction length W11_{c} of the central portion of the metal support layer 11 in the thickness direction is preferably the same as the minimum width-direction length W11ₘᵢₙ of the metal support layer 11. In the present embodiment, in each of the wiring portions 2, the width-direction length of the metal support layer 11 is approximately the same over the thickness direction, and thus satisfies W11ₘₐₓ=W11ₘᵢₙ=W11_{c}.

Further, in each of the wiring portions 2, between the one-side surface of the metal support layer 11 in the thickness direction and the other-side surface, the maximum width-direction length W11ₘₐₓ of the metal support layer 11 may be the same as or different from the width of the wiring portion 2.

In each of the wiring portions 2, the ratio (thickness of the metal support layer 11/W11ₘₐₓ) of the thickness of the metal support layer 11 with respect to the maximum width-direction length W11ₘₐₓ of the metal support layer 11 is, for example, 2 or more, preferably 5 or more, and, for example, 30 or less, preferably 10 or less. Hereinafter, the ratio (thickness of the metal support layer 11/W11ₘₐₓ) of the thickness of the metal support layer 11 with respect to the maximum width-direction length W11ₘₐₓ of the metal support layer 11 in each of the wiring portions 2 is defined as the aspect ratio of the metal support layer 11 in each of the wiring portions 2.

When the aspect ratio of the metal support layer 11 in each of the wiring portions 2 is the above-described lower limit or more, the wiring portion 2 can be easily deformed in the width direction as compared with in the thickness direction. Further, it is possible to ensure the stiffness of the wiring portion 2 in the thickness direction.

In each of the wiring portions 2, the width-direction lengths (W11ₘₐₓ, W11ₘᵢₙ, W11_{c}) of the metal support layer 11 and the aspect ratios of the metal support layer 11 are appropriately adjusted within the above-described ranges, and may be the same as, or may be different from each other.

### (2) Conductor Layer

As shown in FIG. 2, the conductor layer 12 is disposed in each of the wiring portions 2 and the terminal disposition portions 3A and 3B. That is, each of the wiring portions 2 and the terminal disposition portions 3A and 3B include the conductor layer 12.

Further, as shown in FIGS. 2 and 3, the conductor layer 12 is disposed on the one-side surface of the metal support layer 11 in the thickness direction. In other words, the conductor layer 12 is in contact with the one-side surface of the metal support layer 11 in the thickness direction. Preferably, the conductor layer 12 may include a bonding layer (not shown) that bonds the metal support layer 11 and the conductor layer 12. The bonding layer consists of metal. The bonding layer is, for example, a sputtering layer. Examples of the material of the bonding layer include chromium, nickel, titanium, and the alloys thereof. The conductor layer 12 typically does not have a pattern.

The conductivity of the conductor layer 12 is higher than the conductivity of the metal support layer 11. Therefore, forming the wire 141 at one side of the conductor layer 12 in the thickness direction makes it possible to reduce the transmission loss of the wire 141. Examples of the material of the conductor layer 12 include copper, silver, gold, iron, aluminum, chromium, and the alloys thereof. The conductor layer 12 preferably consists of copper. The conductor layer 12 is a plating layer. Therefore, the thickness of the conductor layer 12 can be easily adjusted.

The conductor layer 12 has a thickness of, for example, 0.1 μm or more, preferably 0.5 μm or more, more preferably 1 μm or more, even more preferably 2 μm or more, and, for example, 30 μm or less, preferably 20 μm or less, more preferably 15 μm or less, and even more preferably 10 μm or less.

When the thickness of the conductor layer 12 is the above-described lower limit or more, it is possible to ensure the conductivity of the conductor layer 12. In other words, it is possible to reduce the electrical resistance by electrically conducting the second terminal 151A and the second terminal 151B. When the thickness of the conductor layer 12 is the above-described upper limit or less, it is possible to ensure the flexibility of the wiring portions 2.

The ratio (the thickness of the conductor layer 12/the thickness of the metal support layers 11) of the thickness of the conductor layer 12 with respect to the thickness of the metal support layer 11 is, for example, 0.001 or more, preferably 0.003 or more, 0.005 or more, more preferably 0.01 or more, and, for example, 0.5 or less, preferably 0.3 or less, more preferably 0.1 or less, and even more preferably 0.08 or less.

When the ratio of the thickness of the conductor layer 12 with respect to the thickness of the metal support layer 11 is the above-described lower limit or more, it is possible to ensure the conductivity of the conductor layer 12. In other words, it is possible to reduce the electrical resistance by electrically conducting the second terminal 151A and the second terminal 151B. When the ratio of the thickness of the conductor layer 12 with respect to the thickness of the metal support layer 11 is the above-described upper limit or less, it is possible to adjust the elasticity of the wiring portion 2.

In each of the wiring portions 2, the conductor layer 12 typically covers the entire one-side surface of the metal support layer 11 in the thickness direction. Further, in the terminal disposition portion 3, the conductor layer 12 may cover the entire one-side surfaces of the metal support layers 11 in the thickness direction, or may cover the one-side surfaces of the metal support layers 11 in the thickness direction except for outer peripheral end portions of the metal support layers 11.

In each of the wiring portions 2, the conductor layer 12 has a length W12 in the width direction of, for example, 5 μm to 300 μm, preferably 10 μm to 250 μm, and more preferably 15 μm to 200 μm. In each of the wiring portions 2, the width-direction length W12 of the conductor layer 12 is, for example, 5 μm or more, preferably 10 μm or more, more preferably 15 μm or more, and, for example, 300 μm or less, preferably 250 μm or less, more preferably 200 μm or less.

In each of the wiring portions 2, the width-direction length W12 of the conductor layer 12 is larger than the minimum width-direction length W11ₘᵢₙ of the metal support layer 11. In other words, in each of the wiring portions 2, the width-direction length W12 of the conductor layer 12 is larger than a width-direction length of at least a portion of the metal support layer 11 in the thickness direction.

In each of the wiring portions 2, the ratio (W12/W11ₘᵢₙ) of the width-direction length W12 of the conductor layer 12 with respect to the minimum width-direction length W11ₘᵢₙ of the metal support layer 11 is, for example, 1.0 to 5.0, preferably 1.1 to 5.0, more preferably 1.2 to 4.0, and even more preferably 1.3 to 4.0, particularly preferably 1.4 to 3.0, most preferably 1.5 to 3.0. In each of the wiring portions 2, the ratio (W12/W11ₘᵢₙ) of the width-direction length W12 of the conductor layer 12 with respect to the minimum width-direction length W11ₘᵢₙ of the metal support layer 11 is, for example, more than 1.0, preferably 1.1 or more, more preferably 1.2 or more, even more preferably 1.3 or more, particularly preferably 1.4 or more, most preferably 1.5 or more, and, for example, 5.0 or less, preferably 4.0 or less, more preferably 3.0 or less.

Furthermore, in each of the wiring portions 2, the width-direction length W12 of the conductor layer 12 is preferably larger than the width-direction length W11_{c} of the central portion of the metal support layer 11 in the thickness direction.

In each of the wiring portions 2, the ratio (W12/W11_{c}) of the width-direction length W12 of the conductor layer 12 with respect to the width-direction length W11_{c} of the central portion of the metal support layer 11 is, for example, 1.0 to 5.0, preferably 1.1 to 5.0, more preferably 1.2 to 4.0, even more preferably 1.3 to 4.0, particularly preferably 1.4 to 3.0, most preferably 1.5 to 3.0. In each of the wiring portions 2, the ratio (W12/W11_{c}) of the width-direction length W12 of the conductor layer 12 with respect to the width-direction length W11_{c} of the central portion of the metal support layer 11 is, for example, larger than 1.0, preferably 1.1 or more, more preferably 1.2 or more, even more preferably 1.3 or more, particularly more preferably 1.4 or more, most preferably 1.5 or more, and, for example, 5.0 or less, preferably 4.0 or less, more preferably 3.0 or less.

Further, in each of the wiring portions 2, the width-direction length W12 of the conductor layer 12 may be larger than the maximum width-direction length W11ₘₐₓ of the metal support layer 11, may be smaller than the maximum width-direction length W11ₘₐₓ of the metal support layer 11, may be the same as the maximum width-direction length W11ₘₐₓ of the metal support layer 11. In the present embodiment, in each of the wiring portions 2, the width-direction length W12 of the conductor layer 12 is larger than the maximum width-direction length W11ₘₐₓ of the metal support layer 11.

In each of the wiring portions 2, the ratio (W12/W11ₘₐₓ) of the width-direction length W12 of the conductor layer 12 with respect to the maximum width-direction length W11ₘₐₓ of the metal support layer 11 is, for example, 1.0 to 4.0, preferably 1.2 to 4.0, more preferably 1.5 to 3.0. In each of the wiring portions 2, the ratio (W 12/ W11ₘₐₓ) of the width-direction length W12 of the conductor layer 12 with respect to the maximum width-direction length W11ₘₐₓ of the metal support layer 11 is, for example, 1.0 or more, preferably 1.3 or more, more preferably 1.5 or more, and, for example, 4.0 or less, preferably 3.5 or less, more preferably 3.0 or less.

### (3) Insulating Layer

As shown in FIGS. 2 and 3, the insulating layer 13 (base insulating layer) is disposed in each of the wiring portions 2 and the terminal disposition portions 3A and 3B. That is, each of the wiring portions 2 and the terminal disposition portions 3A and 3B include the insulating layer 13.

As shown in FIGS. 2 and 3, the insulating layer 13 (base insulating layer) is disposed on the one-side surface of the conductor layer 12 in the thickness direction.

In each of the wiring portions 2, the insulating layer 13 is disposed between the conductor layer 12 and the wire 141. The insulating layer 13 insulates the conductor layer 12 from the wire 141. In the terminal disposition portions 3A and 3B, the insulating layer 13 is disposed between the conductor layer 12 and the first terminals 142A and 142B. The insulating layer 13 insulates the conductor layer 12 from the first terminals 142A and 142B. That is, the insulating layer 13 is disposed between the conductor layer 12 and the first circuit pattern 14 to insulate the conductor layer 12 from the first circuit pattern 14. In the terminal disposition portions 3A and 3B, when a portion where the conductor layer 12 is not disposed is present, the insulating layer 13 may be disposed on the one-side surfaces of the metal support layer 11 in the thickness direction.

Further, in the present embodiment, in the terminal disposition portions 3A and 3B, the insulating layer 13 includes a plurality of through holes 131. More specifically, the insulating layer 13 includes one through hole 131 in each of the terminal disposition portions 3A and 3B. The insulating layer 13 may not include a through hole 131.

In the present embodiment, in the terminal disposition portions 3A and 3B, the insulating layer 13 includes the through holes 131 at positions where the second terminals 151A and 151B are disposed. The insulating layer 13 does not insulate the conductor layer 12 from the second terminals 151A and 151B. That is, the insulating layer 13 does not insulate the conductor layer 12 from the second circuit pattern 15. The second terminals 151A and 151B are electrically connected to the conductor layer 12 through the through holes 131 of the insulating layer 13. In the terminal disposition portions 3A and 3B, the insulating layer 13 except the through holes 131 may be disposed between the conductor layer 12 and the second terminals 151A and 151B.

The shape of the through holes 131 viewed from the thickness direction (in a plan view) is not particularly limited. In the present embodiment, the through holes 131 with an approximately circle shape in the plan view is shown as an example. Further, the shape of the through holes 131 in a cross-sectional view is not particularly limited. As shown in FIG. 2, in the present embodiment, the through holes 131 with an approximately straight shape in the cross-sectional view is shown as an example.

Between the conductor layer 12 and the insulating layer 13, and between the metal support layer 11 and the insulating layer 13, a protective metal layer (not shown) that protects the metal support layer 11 and the conductor layer 12 may be disposed. In other words, the metal support layer 11 and the conductor layer 12 may include the protective metal layer. The protective metal layer consists of metal. The protective metal layer is, for example, a sputtering layer. Examples of the material of the protective metal layer include chromium, nickel, titanium, and an alloy thereof.

The insulating layer 13 is made of resin. Examples of the resin include polyimide, maleimide, epoxy resin, polybenzoxazole, and polyester. Preferably, polyimide is used.

The insulating layer 13 has a thickness of, for example, 1 μm or more, preferably 5 μm or more, and for example, 100 μm or less, preferably 50 μm or less.

### (4) Circuit Pattern

As shown in FIGS. 2 and 3, the circuit pattern is disposed at one side of the conductor layer 12 in the thickness direction.

The circuit pattern includes the first circuit pattern 14 including the wires 141, and a second circuit pattern 15 electrically connected to the conductor layer 12 and independent from the first circuit pattern 14. The first circuit pattern 14 preferably includes the wire 141 and the first terminals 142A and 142B, both of which are connected to the wire 141. Further, the second circuit pattern 15 preferably includes the second terminals 151A and 151B.

### (4-1) First Circuit Pattern

The first circuit pattern 14 is disposed on the one-side surface of the insulating layer 13 in the thickness direction. In other words, the first circuit pattern 14 is in contact with the one-side surface of the insulating layer 13 in the thickness direction. Further, the first circuit pattern 14 is disposed at one side of the conductor layer 12 in the thickness direction. The first circuit pattern 14 overlaps the entire conductor layer 12 in the thickness direction. The first circuit pattern 14 is disposed at a side opposite to the conductor layer 12 with respect to the insulating layer 13 in the thickness direction. The first circuit pattern 14 is disposed away from the conductor layer 12 in the thickness direction. The first circuit pattern 14 is independent from the conductor layer 12.

The first circuit pattern 14 consists of metal. Examples of the metal include copper, silver, gold, iron, aluminum, chromium, and an alloy thereof. The first circuit pattern 14 preferably consists of copper. In the present embodiment, the wires 141 of the first circuit pattern 14 and the first terminals 142A and 142B of the first circuit pattern 14 are made of the same metal. The shape of the first circuit pattern 14 in the plan view is not limited.

The first circuit pattern 14 includes a plurality of wires 141. The first circuit pattern 14 preferably includes a plurality of wires 141 and a plurality of first terminals 142A and 142B connected to the wires 141.

### [Wires]

A plurality of wires 141 are disposed in the wiring portions 2. Portions of each of the plurality of wires 141 may be disposed in the terminal disposition portions 3A and 3B, respectively.

Each of the wires 141 is disposed on the one-side surface of the insulating layer 13 in the thickness direction. Then, each of the wires 141 is disposed at one side of the conductor layer 12 in the thickness direction. Therefore, it is possible to reduce the transmission loss of the wires 141.

In the wiring portions 2, each of the plurality of wires 141 extends in the first direction. In the wiring portions 2, the plurality of wires 141 are aligned in the second direction. The plurality of wires 141 are disposed away from each other at intervals in the second direction. The wires 141 electrically connect the first terminals 142 A to the first terminals 142B. Specifically, one end portions of the wires 141 in the first direction are connected to the first terminals 142A, the other end portions of the wires 141 in the first direction are connected to the first terminals 142B.

Examples of the wires 141 include signal wiring (e.g., differential wiring), power supply wiring, a ground line, and an antenna line.

As shown in FIG. 3, the shape of each of the wires 141 in the cross-sectional view is approximately rectangular.

The wires 141 each have a thickness of, for example, 5 μm to 50 μm, and preferably 7 μm to 45 μm.

The wires 141 each have a length in the width direction of, for example, 1 μm or more, preferably 5 μm or more, and, for example, 50 μm or less, preferably 30 μm or less.

The width-direction length of each of the wires 141 is preferably smaller than the width-direction length W12 of the conductor layer 12 in each of the wiring portions 2.

### [First Terminal]

A plurality of first terminals 142A is disposed in the terminal disposition portion 3A. The plurality of first terminals 142A are aligned along the second direction. The plurality of first terminals 142A are disposed away from each other at intervals in the second direction. The plurality of first terminals 142A are connected to the one end portions of the plurality of wires 141 in the first direction, respectively.

A plurality of first terminals 142B is disposed in the terminal disposition portion 3B. The plurality of first terminals 142B are aligned along the second direction. The plurality of first terminals 142B are disposed away from each other at intervals in the second direction. The plurality of first terminals 142B are connected to the other end portions of the plurality of wires 141 in the first direction, respectively.

In the terminal disposition portions 3A and 3B, the plurality of first terminals 142A and 142B is disposed on the one-side surface of the insulating layer 13 in the thickness direction.

Each of the plurality of first terminals 142A and 142B has, for example, a square land shape. The shape (not shown) of each of the first terminals 142A and 142B in the cross-sectional view is not particularly limited, and, for example, approximately rectangular.

The first terminals 142A and 142B each have a thickness of, for example, 5 μm to 50 μm, preferably 7 μm to 45 μm. The thickness of each of the first terminals 142A and 142B may be the same as the thickness of each of the wires 141, or may be different. In the present embodiment, the thickness of each of the first terminals 142A and 142B is the same as each of the thickness of the wires 141.

The first terminals 142A and 142B each have a length in the width direction of, for example, 15 μm or more, preferably 40 μm or more, and, for example, 500 μm or less, preferably 300 μm or less. The width-direction length of each of the first terminals 142A and 142B is preferably larger than the width-direction length of each of the wires 141. The width-direction length of each of the first terminals 142A and 142B indicates the maximum length in the width direction.

### (4-2) Second Circuit Pattern

The second circuit pattern 15 is electrically connected to the conductor layer 12. As long as the second circuit pattern 15 is electrically connected to the conductor layer 12, the disposition thereof is not particularly limited. In the present embodiment, as shown in FIG. 2, the second circuit pattern 15 is electrically connected to the conductor layer 12 through the through holes 131 of the insulating layer 13. In other words, the second circuit pattern 15 is disposed in the through holes 131 of the insulating layer 13, and in contact with the one-side surface of the conductor layer 12 in the thickness direction. A portion of the second circuit pattern 15 may be disposed on the one-side surface of the insulating layer 13 in the thickness direction. More specifically, in the present embodiment, the second circuit pattern 15 is disposed in the through holes 131 of the insulating layer 13 and on the one-side surface of the insulating layer 13 in the thickness direction. The second circuit pattern 15 is independent from the first circuit pattern 14.

When the insulating layer 13 does not include a through hole 131, the second circuit pattern 15 is disposed on the one-side surface of the insulating layer 13 in the thickness direction and the side portions of the insulating layer 13 in a plane direction, and is electrically connected to the conductor layer 12.

The second circuit pattern 15 consists of metal. Examples of the metal include copper, silver, gold, iron, aluminum, chromium, and an alloy thereof. The second circuit pattern 15 preferably consists of copper. The second circuit pattern 15 may consist of the same metal as the first circuit pattern 14. The shape of the second circuit pattern 15 in the plan view is not limited.

The second circuit pattern 15 includes, for example, a plurality of second terminals 151A and 151B. The second circuit pattern 15 does not include a wire.

### [Second Terminal]

The second terminals 151A and 151B are disposed in the terminal disposition portions 3A and 3B. Specifically, in the terminal disposition portions 3A and 3B, the second terminals 151A and 151B are disposed in the through holes 131 of the insulating layer 13, and connected to the conductor layer 12. The second terminal 151A and the second terminal 151B are connected to the conductor layer 12 through the through holes 131 of the insulating layer 13.

The second terminal 151A is disposed in the terminal disposition portion 3A. In the present embodiment, one second terminal 151A is disposed in the terminal disposition portion 3A. A plurality of second terminals 151A may be disposed in the terminal disposition portion 3A. Further, in the terminal disposition portion 3A, the disposition of the second terminal 151A is not particularly limited. In the present embodiment, the second terminal 151A is disposed away at one side of the first terminal 142A in the first direction.

The second terminal 151A is connected to the conductor layer 12 through the through hole 131 of the insulating layer 13. More specifically, in the terminal disposition portion 3A, a metal for forming the above-described second terminal 151A (second circuit pattern 15) is filled in the through hole 131 of the insulating layer 13 to form the second terminal 151A, and the second terminal 151A and the conductor layer 12 are contacted and electrically connected to each other. The second terminal 151A is not connected to the wires 141 and the first terminals 142A.

The second terminal 151B is disposed in the terminal disposition portion 3B. In the present embodiment, one second terminal 151B is disposed in the terminal disposition portion 3B. A plurality of second terminals 151B may be disposed in the terminal disposition portion 3B. Further, in the terminal disposition portion 3B, the disposition of the second terminal 151B is not particularly limited. In the present embodiment, the second terminal 151B is disposed away at the other side of the first terminal 142B in the first direction.

The second terminal 151B is connected to the conductor layer 12 through the through hole 131 of the insulating layer 13. More specifically, in the terminal disposition portion 3B, a metal for forming the above-described second terminal 151B (second circuit pattern 15) is filled in the through hole 131 of the insulating layer 13 to form the second terminal 151B, and the second terminal 151B and the conductor layer 12 are contacted and electrically connected to each other. The second terminal 151B is not connected to the wires 141 and the first terminals 142B.

Each of the plurality of second terminals 151A and 151B has, for example, a square land shape.

The shape of each of the plurality of second terminals 151A and 151B in the cross-sectional view is not specifically limited, and examples thereof include an approximately rectangular shape and an approximately T shape.

The second terminals 151A and 151B each have a thickness of, for example, 5 μm to 50 μm, preferably 7 μm to 45 μm. The thickness of each of the second terminals 151A and 151B may be the same as or may be different from the thickness of each of the wires 141 and the first terminals 142A and 142B. In the present embodiment, the thickness of each of the second terminals 151A and 151B is the same as the thickness of each of the wires 141 and the first terminals 142A and 142B.

The second terminals 151A and 151B each have a length in the width direction of, for example, 15 μm or more, preferably 40 μm or more, and, for example, 500 μm or less, preferably 300 μm or less. The width-direction length of each of the second terminals 151A and 151B is preferably larger than the width-direction length of each of the wires 141. The width-direction length of each of the second terminals 151A and 151B indicates the maximum length in the width direction.

### (6) Cover Insulating Layer

As shown in FIGS. 1 and 2, the cover insulating layer 16 covers all of the wires 141 in the wiring portions 2. Further, the covering insulating layer 16 may cover at least a portion of the wires 141 which is disposed in the terminal disposition portions 3A and 3B.

As shown in FIGS. 1 and 2, the cover insulating layer 16 does not cover the first terminals 142A and 142B and the second terminals 151A and 151B.

The cover insulating layer 16 is disposed at one side of the insulating layer 13 (base insulating layer) in the thickness direction. The cover insulating layer 16 is made of resin. Examples of the resin include polyimide, maleimide, epoxy resin, polybenzoxazole, and polyester. Preferably, polyimide is used.

### 2. Method of Producing Wiring Circuit Board

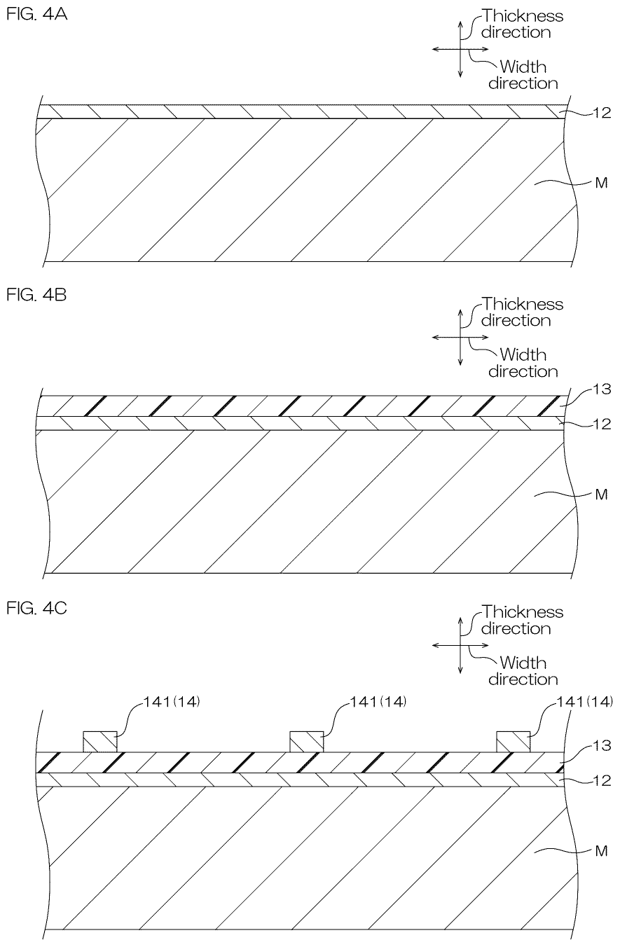

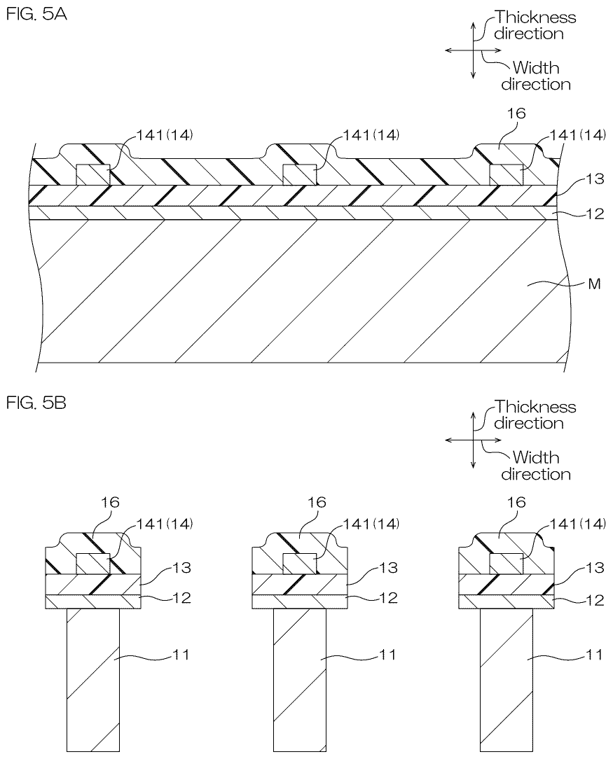

Next, with reference to FIGS. 4A to 5B, a method of producing the wiring circuit board 1 is described.

The method of producing the wiring circuit board 1 includes a conductor layer forming step (see FIG. 4A), an insulating layer forming step (see FIG. 4B), a circuit pattern forming step (see FIG. 4C), a cover insulating layer forming step (see FIG. 5A), and an etching step (see FIG. 5B).

### (1) Conductor Layer Forming Step

As shown in FIG. 4A, in the conductor layer forming step, a conductor layer 12 is formed on a one-side surface of a substrate M made of metal (e.g., metal foil) in the thickness direction.

In detail, first, on the one-side surface of the substrate M in the thickness direction, the above-described bonding layer (not shown) is formed. The bonding layer is formed, for example, by sputtering.

Next, the bonding layer is coated with a plating resist.

Next, the plating resist is exposed to light and developed. Then, the plating resist in the portion where the conductor layer 12 is to be formed is removed, and the bonding layer is exposed in the portion where the conductor layer 12 is to be formed. On the other hand, the plating resist in the portion where the conductor layer 12 is not formed remains.

Next, a conductor layer 12 is formed on the exposed one-side surface of the bonding layer in the thickness direction by electrolytic plating. After the electrolytic plating is completed, the plating resist is released.

In this manner, a conductor layer 12 is formed on the one-side surface of the substrate M in the thickness direction.

When the conductor layer 12 is formed on the entire one-side surface of the substrate M in the thickness direction, the above-described steps of covering with the plating resist, exposure, and development are not included.

### (2) Insulating Layer Forming Step (Base Insulating Layer Forming Step)

Next, as shown in FIG. 4B, in the insulating layer forming step, an insulating layer 13 (base insulating layer) is formed on a one-side surface of the conductor layer 12 in the thickness direction.

In detail, in the insulating layer forming step, first, the above-described protective metal layer (not shown) is formed on the one-side surfaces of the substrate M and the conductor layer 12 in the thickness direction. The protective metal layer is formed, for example, by sputtering.

Next, a solution (varnish) of a photosensitive resin is applied to on the one-side surfaces of the substrate M and the conductor layer 12 in the thickness direction (the one-side surface of the protective metal layer in the thickness direction) and dried to form a coating film of the photosensitive resin. Next, the coating film of the photosensitive resin is exposed to light and developed. In this manner, the insulating layer 13 is obtained.

Although not shown, in the terminal disposition portions 3A and 3B, the insulating layer 13 is not disposed in a position where a through hole 131 is to be formed in the insulating layer 13. In detail, the coating film of the photosensitive resin is formed on the one-side surfaces of the substrate M and the conductor layer 12 in the thickness direction (the one-side surface of the protective metal layer in the thickness direction), and thereafter the position where a through hole 131 is to be formed is shielded from light, for example, by a photomask. Then, the insulating layer 13 in the shielded portion is removed by the development, thereby forming a through hole 131.

### (3) Circuit Pattern Forming Step

Next, as shown in FIG. 4C, in the circuit pattern forming step, a circuit pattern is formed. Specifically, a first circuit pattern 14 is formed on the one-side surface of the insulating layer 13 in the thickness direction, and a second circuit pattern 15 is formed on the one-side surface of the conductor layer 12 in the thickness direction in the through hole 131 of the insulating layer 13.

In detail, first, a seed layer (not shown) is formed on the one-side surface of the insulating layer 13 in the thickness direction, the inner peripheral surface of the through hole 131 of the insulating layer 13, and the one-side surface of the conductor layer 12 exposed in the through hole 131 of the insulating layer 13 in the thickness direction. The seed layer is formed, for example, by sputtering. Examples of the material of the seed layer include, for example, chromium, copper, nickel, titanium, and the alloys thereof.

Next, a plating resist is attached to the one-side surface of the seed layer in the thickness direction. Then, while the portions where the wires 141 of the first circuit pattern 14, the first terminals 142A and 142B of the first circuit pattern 14, and the second terminals 151A and 151B of the second circuit pattern 15 are to be formed are shielded from light, the plating resist is exposed to light.

Next, the exposed plating resist is developed. Then, the plating resist in the shielded portions is removed, and the seed layer is exposed in the portions where the wires 141 of the first circuit pattern 14, the first terminals 142A and 142B of the first circuit pattern 14, and the second terminals 151A and 151B of the second circuit pattern 15 are to be formed. On the other hand, the plating resist in the exposed portion remains.

Next, the wires 141 of the first circuit pattern 14, the first terminals 142A and 142B of the first circuit pattern 14, and the second terminals 151A and 151B of the second circuit pattern 15 are formed on the exposed seed layer by electrolytic plating.

After the wires 141 of the first circuit pattern 14, the first terminals 142A and 142B of the first circuit pattern 14, and the second terminals 151A and 151B of the second circuit pattern 15 are formed, the plating resist is released.

### (4) Cover Insulating Layer Forming Step

Next, as shown in FIG. 5A, in the cover insulating layer forming step, a cover insulating layer 16 is formed so as to cover the one-side surface of the insulating layer 13 in the thickness direction and the circuit pattern. The cover insulating layer 16 is formed, for example, in the same manner as the formation of the above-described insulating layer 13.

### (5) Etching Step

Next, in the etching step, the substrate M is etched to form a metal support layer 11 shown in FIG. 5B.

In this manner, the wiring circuit board 1 shown in FIG. 1 is produced.

### 3. Operations and Effects

(1) According to the circuit board 1, in each of the wiring portions 2, the width-direction length of the conductor layer 12 is larger than the width-direction length of at least a portion of the metal support layer 11 in the thickness direction (the minimum width-direction length W11ₘᵢₙ). Therefore, it is possible to reduce the electrical resistance.

In detail, the miniaturization of the wiring circuit board 1 is required, and thus it is necessary to prevent the width-direction length of the metal support layer 11 from being excessively large in each of the wiring portions 2. Therefore, in each of the wiring portions 2, the width-direction length of the conductor layer 12 is larger than the width-direction length of at least a portion of the metal support layer 11 in the thickness direction (the minimum width-direction length W11ₘᵢₙ). Thus, it is possible to reduce the electrical resistance while achieving the miniaturization.

(2) The wiring circuit board 1 includes the metal support layer 11, the conductor layer 12, the insulating layer 13, and the circuit pattern in order toward one side in the thickness direction, and the circuit pattern includes the first circuit pattern 14 having a wire 141. That is, the wire 141 is formed at the one side of the conductor layer 12 in the thickness direction. Therefore, it is possible to reduce the transmission loss of the wire 141.

(3) According to the wiring circuit board 1, in each of the wiring portions 2, the width-direction length W12 of the conductor layer 12 is larger than the width-direction length of at least a portion of the metal support layer 11 in the thickness direction (the minimum width-direction length W11ₘᵢₙ), and, in each of the wiring portions 2, the width-direction length W12 of the conductor layer 12 is larger than the width-direction length W11_{c} of the central portion of the metal support layer 11 in the thickness direction. Therefore, it is possible to further reduce the electrical resistance.

(4) According to the wiring circuit board 1, the circuit pattern includes the second circuit pattern 15 independent from the first circuit pattern 14, and the insulating layer 13 includes a through hole 131. Then, the second circuit pattern 15 is electrically connected to the conductor layer 12 through the through hole 131. Therefore, the second circuit pattern 15 can be reliably connected to the conductor layer 12.

(5) According to the wiring circuit board 1, the first circuit pattern 14 includes the first terminals 142A and 142B connected to the wire 141, and the second circuit pattern 15 includes the second terminals 151A and 151B, and the first terminals 142A and 142B and the second terminals 151A and 151B are disposed in the terminal disposition portion 3. Then, in the terminal disposition portion 3, the second terminals 151A and 151B are disposed in the through holes 131. Therefore, it is possible to allow the second circuit pattern 15 to be independent from the first circuit pattern 14, and reliably connect the second terminals 151A and 151B to the conductor layer 12.

(6) According to the circuit board 1, in each of the wiring portions 2, with respect to the minimum width-direction length W11ₘᵢₙ of the metal support layer 11, the ratio of the width-direction length W12 of the conductor layer 12 is 1.2 or more. Therefore, it is possible to further reduce the electrical resistance.

(7) According to the circuit board 1, in each of the wiring portions 2, with respect to the width-direction length W11_{c} of the central portion of the metal support layer 11 in the thickness direction, the ratio of the width-direction length W12 of the conductor layer 12 is 1.2 or more. Therefore, it is possible to further reduce the electrical resistance.

(8) According to the wiring circuit board 1, with respect to the thickness of the metal support layer 11, the ratio of the thickness of the conductor layer 12 is 0.003 or more. Therefore, it is possible to further reduce the electrical resistance.

### 5. Modified Examples

Next, modified examples are described. In the modified examples, the same members as in the above-described embodiment are given the same numerical references, and the descriptions thereof are omitted.

(1) In the above-described one embodiment of the wiring circuit board 1, in each of the wiring portions 2, the shape of the metal support layer 11 in the cross-sectional view is an approximately rectangular shape, and in each of the wiring portions 2, the width-direction length of the metal support layer 11 is approximately the same over the thickness direction, but the shape and the length are not limited thereto.

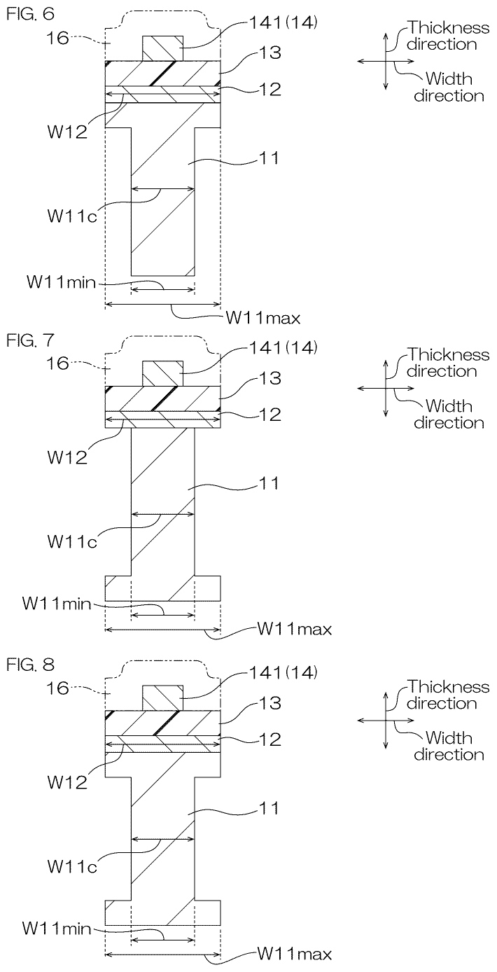

As shown in FIG. 6, in the wiring circuit board 1 of the first modified example, in each of the wiring portions 2, the shape of the metal support layer 11 in the cross-sectional view is an approximately T-shape.

In each of the wiring portions 2, a width-direction length of a one end portion of the metal support layer 11 in the thickness direction is larger than the width-direction length of the central portion of the metal support layer 11 in the thickness direction and a width-direction length of the other end portion of the metal support layer 11 in the thickness direction. In each of the wiring portions 2, the maximum width-direction length W11ₘₐₓ of the metal support layer 11 is the width-direction length of the one end portion of the metal support layer 11 in the thickness direction.

In each of the wiring portions 2, the width-direction length W11_{c} of the central portion of the metal support layer 11 in the thickness direction is the same as the minimum width-direction length W11ₘᵢₙ of the metal support layer 11.

In other words, in the wire circuit board 1 of the first modified example, the width-direction lengths of the metal support layer 11 in each of the wiring portions 2 satisfy W11ₘₐₓ>W11ₘᵢₙ=W11_{c}.

(2) As shown in FIG. 7, in the wiring circuit board 1 of the second modified example, in each of the wiring portions 2, the shape of the metal support layer 11 in the cross-sectional view is an approximately inverted T-shape.

In each of the wiring portions 2, the width-direction length of the other end portion of the metal support layer 11 in the thickness direction is larger than the width-direction length of the one end portion of the metal support layer 11 in the thickness direction and the width-direction length of the central portion of the metal support layer 11 in the thickness direction. In each of the wiring portions 2, the maximum width-direction length W11ₘₐₓ of the metal support layer 11 is the width-direction length of the other end portion of the metal support layer 11 in the thickness direction.

In each of the wiring portions 2, the width-direction length W11_{c} of the central portion of the metal support layer 11 in the thickness direction is the same as the minimum width-direction length W11ₘᵢₙ of the metal support layer 11.

In other words, in the wire circuit board 1 of the second modified example, the width-direction lengths of the metal support layer 11 in each of the wiring portions 2 satisfy W11ₘₐₓ>W11ₘᵢₙ=W11_{c}.

(3) As shown in FIG. 8, in the wiring circuit board 1 of the third modified example, in each of the wiring portions 2, the shape of the metal support layer 11 in the cross-sectional view is an approximately I-shape.

In each of the wiring portions 2, the width-direction length of the one end portion of the metal support layer 11 in the thickness direction and the width-direction length of the other end portion of the metal support layer 11 in the thickness direction are larger than the width-direction length W11_{c} of the central portion of the metal support layer 11 in the thickness direction. In each of the wiring portions 2, the maximum width-direction length W11ₘₐₓ of the metal support layer 11 is the width-direction length of the one end portion of the metal support layer 11 in the thickness direction, or the width-direction length of the other end portion of the metal support layer 11 in the thickness direction, or both of the width-direction length of the one end portion of the metal support layer 11 in the thickness direction and the width-direction length of the other end portion of the metal support layer 11 in the thickness direction.

In each of the wiring portions 2, when the width-direction length of the one end portion of the metal support layer 11 in the thickness direction and the width-direction length of the other end portion of the metal support layer 11 in the thickness direction are larger than the width-direction length W11_{c} of the central portion of the metal support layer 11 in the thickness direction, it is possible to increase the surface area of the metal support layer 11 in each of the wiring portions 2. As a result, the heat dissipation can be improved. Further, in the second direction, it is possible to reduce the risk that the metal support layers 11 of the adjacent wiring portions 2 are brought into contact to each other.

In each of the wiring portions 2, the width-direction length W11_{c} of the central portion of the metal support layer 11 in the thickness direction is the same as the minimum width-direction length W11ₘᵢₙ of the metal support layer 11.

In other words, in the wire circuit board 1 of the third modified example, the width-direction lengths of the metal support layer 11 in each of the wiring portions 2 satisfy W11ₘₐₓ>W11ₘᵢₙ=W11_{c}.

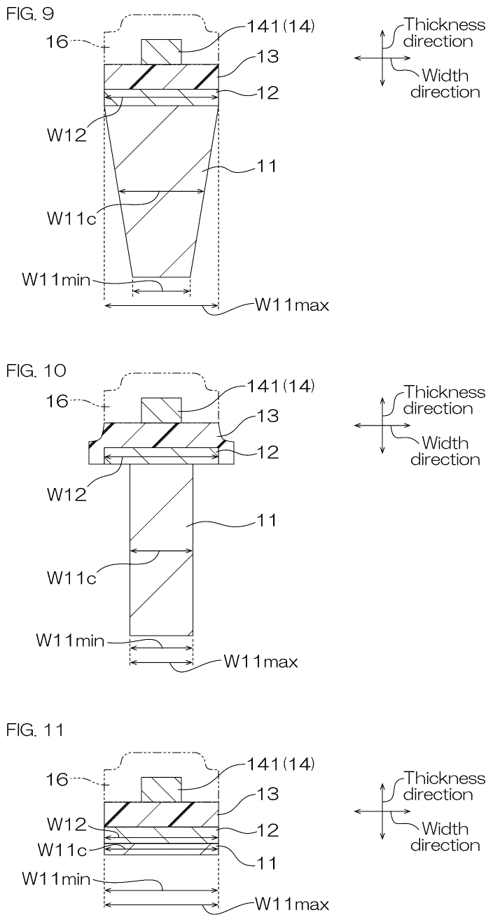

(4) As shown in FIG. 9, in the wiring circuit board 1 of the fourth modified example, in each of the wiring portions 2, the metal support layer has an approximately tapered shape in a cross-sectional view, which extends from the other side in the thickness direction toward one side. In other words, in each of the wiring portions 2, the shape of the metal support layer 11 in the cross-sectional view is an approximately tapered shape extending from the other side in the thickness direction toward one side.

In each of the wiring portions 2, the width-direction length of the one end portion of the metal support layer 11 in the thickness direction is larger than the width-direction length of the central portion of the metal support layer 11 in the thickness direction and the width-direction length of the other end portion of the metal support layer 11 in the thickness direction. In each of the wiring portions 2, the maximum width-direction length W11ₘₐₓ of the metal support layer 11 is the width-direction length of the one end portion of the metal support layer 11 in the thickness direction. Further, in each of the wiring portions 2, the width-direction length of the central portion of the metal support layer 11 in the thickness direction is larger than the width-direction length of the other end portion of the metal support layer 11 in the thickness direction.

In each of the wiring portions 2, the width-direction length W11_{c} of the central portion of the metal support layer 11 in the thickness direction differs from the maximum width-direction length W11ₘₐₓ of the metal support layer 11 and the minimum width-direction length W11ₘᵢₙ of the metal support layer 11.

That is, in the wiring circuit board 1 of the fourth modified example, the width-direction lengths of the metal support layer 11 in each of the wiring portions 2 satisfy W11ₘₐₓ>W11_{c}>W11ₘᵢₙ.

(5) In the above-described one embodiment of the wiring circuit board 1, in each of the wiring portions 2, the insulating layer 13 is disposed only on the one-side surface of the conductor layer 12 in the thickness direction, but the disposition of the insulating layer 13 is not limited thereto.

As shown in FIG. 10, in the wiring circuit board 1 of the fifth modified example, in each of the wiring portions 2, the insulating layer 13 is disposed so as to cover the conductor layer 12. Specifically, in the wiring portion 2, the insulating layer 13 is disposed so as to cover the one-side surface of the conductor layer 12 in the thickness direction and both surfaces of the conductor layer 12 in the width direction.

In the wiring circuit board 1 of the fifth modified example, the width-direction length of the wiring portion 2 is the width-direction length of the insulating layer 13.

(6) In the above-described one embodiment of the circuit board 1, in each of the wiring portions 2, the aspect ratio of the metal support layer 11 (the thickness of the metal support layer 11/W11ₘₐₓ of the metal support layer 11) is relatively large (e.g., 2 or more), but not limited thereto.

As shown in FIG. 11, in the wire circuit board 1 of the sixth modified example, in each of the wiring portions 2, the aspect ratio of the metal support layer 11 (the thickness of the metal support layer 11/W11ₘₐₓ of the metal support layer 11) is relatively small. In each of the wiring portions 2, the aspect ratio of the metal support layer 11 (the thickness of the metal support layer 11/W11ₘₐₓ of the metal support layer 11) is, for example, 0.5 or more, preferably 1.0 or more, and, for example, less than 2, preferably 1.5 or less.

When the aspect ratio of the metal support layer 11 in each of the wiring portions 2 is the above-described upper limit or less, the wiring portion 2 can easily be deformed in the thickness direction as compared with in the width direction. Further, it is possible to ensure the stiffness of the wiring portion 2 in the width direction.

While the illustrative embodiments of the present invention are provided in the above-described description, such is for illustrative purpose only and it is not to be construed as limiting the scope of the present invention. Modification and variation of the present invention that will be obvious to those skilled in the art is to be covered by the following claims.

### INDUSTRIAL APPLICABILITY

The wiring circuit board of the present invention can be used for connecting electronic components.

### DESCRIPTION OF REFERENCE NUMERALS

1 Wiring circuit board
2 Wiring portion
3 Terminal disposition portion
11 Metal support layer
12 Conductor layer
13 Insulating layer (base insulating layer)
14 First circuit pattern
15 Second circuit pattern
16 Cover insulating layer
131 Through hole
141 Wire
142 First terminal
151 Second terminal

1. A wiring circuit board comprising: a metal support layer, a conductor layer, an insulating layer, and a circuit pattern in order toward one side in a thickness direction,
wherein the circuit pattern includes a first circuit pattern having a wire, and a second circuit pattern electrically connected to the conductor layer and independent from the first circuit pattern,
wherein the wiring circuit board includes a wiring portion in which the wire is disposed, and
wherein in the wiring portion, a width-direction length of the conductor layer in a width direction perpendicular to the thickness direction and a direction in which the wire extends is larger than a width-direction length of at least a portion of the metal support layer in the thickness direction.

2. The wiring circuit board according to claim 1,
wherein in the wiring portion, the width-direction length of the conductor layer is larger than a width-direction length of a central portion of the metal support layer in the thickness direction.

3. The wiring circuit board according to claim 1,
wherein in the wiring portion, a width-direction length of one end portion of the metal support layer in the thickness direction and a width-direction length of an other end portion of the metal support layer in the thickness direction are each larger than a width-direction length of a central portion of the metal support layer in the thickness direction.

4. The wiring circuit board according to claim 1,
wherein the metal support layer of the wiring portion has an approximately tapered shape in a cross-sectional view, the approximately tapered shape extending in the width direction toward the one side in the thickness direction from the other side.

5. The wiring circuit board according to claim 1,
wherein the insulating layer includes a through hole, and
wherein the second circuit pattern is electrically connected to the conductor layer through the through hole.

6. The wiring circuit board according to claim 5,
wherein the first circuit pattern includes a first terminal connected to the wire,
wherein the second circuit pattern includes a second terminal,
wherein the wiring circuit board further includes a terminal disposition portion in which the first terminal and the second terminal are disposed, and
wherein in the terminal disposition portion, the insulating layer includes the through hole, and the second terminal is disposed in the through hole.

7. The wiring circuit board according to claim 1,
wherein in the wiring portion, a ratio of the width-direction length of the conductor layer with respect to a minimum width-direction length of the metal support layer is 1.2 or more.

8. The wiring circuit board according to claim 1,
wherein in the wiring portion, a ratio of the width-direction length of the conductor layer with respect to a width-direction length of a central portion of the metal support layer in the thickness direction is 1.2 or more.

9. The wiring circuit board according to claim 1,
wherein a ratio of a thickness of the conductor layer with respect to a thickness of the metal support layer is 0.003 or more.
